(19) United States
(12) Patent Application Publication
(10) Pub. No.: US 2009/0315819 A1
(43) Pub. Date: Dec. 24, 2009

(54) SOURCE DRIVER AND LIQUID CRYSTAL DISPLAY

(75) Inventor: Li-Chun Huang, Yunlin County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVATEK MICROELECTRONICS CORP., Hsinchu (TW)

(21) Appl. No.: 12/203,931

(22) Filed: Sep. 4, 2008

(30) Foreign Application Priority Data
Jun. 20, 2008 (TW) 97123184

(51) Int. Cl. G09G 3/36; H03M 1/66

(52) U.S. Cl. 345/98; 341/144

(57) ABSTRACT

A source driver and a liquid crystal display are provided. The source driver includes a plurality of pads, a first conducting wire, a second conducting wire, a plurality of first digital-to-analog converters (DACs), and a plurality of second DACs. The first conducting wire is coupled to a first voltage and the first DACs. The second conducting wire is coupled to a second voltage and the second DACs. The first DACs are disposed in a first layer. Output terminals of the first DACs are respectively coupled to a plurality of first pads included in the said pads. The second DACs are disposed in a second layer above the first layer. Output terminals of the second DACs are respectively coupled to a plurality of second pads included in the said pads. Thereby, the transmission quality of the conducting wires for transmitting signals is increased.

### CROSS-REFERENCE TO RELATED APPLICATION

This application claims the priority benefit of Taiwan application serial no. 97123184, filed Jun. 20, 2008. The entirety of the above-mentioned patent application is hereby incorporated by reference herein and made a part of this specification.

### BACKGROUND OF THE INVENTION

1. Field of the Invention

The present invention relates to a liquid crystal display. More particularly, the present invention relates to a source driver.

2. Description of Related Art

Source driver is an important component within a thin film transistor liquid crystal display (TFT LCD), which can convert a digital signal required for displaying images into an analog signal, and transmits the analog signal to each sub-pixel (or referred to as dot) of the TFT LCD.

Generally, buffer amplifiers of the source driver are disposed between digital-to-analog converters (DAC) and output pads, though such method requires a plenty of buffer amplifiers. To reduce the quantity of the buffer amplifiers within the source driver, the DACs are disposed between the buffer amplifiers and the output pads according to the conventional technique, detailed description thereof is as follows.

FIG. 1 is a schematic diagram illustrating a conventional LCD. Referring to FIG. 1, only a display panel 20 and a source driver 30 are illustrated in the LCD 10. The DACs DR1-DR100, DG1-DG100 and DB1-DB100 of the source driver 30 are disposed between buffer amplifiers 41 and 42 and pads R1-R100, G1-G100 and B1-B100. The pads R1-R100, G1-G100 and B1-B100 are respectively coupled to data lines DL of the display panel 20.

The buffer amplifiers 41 and 42 are used for providing a gamma voltage to the DACs DR1-DR100, DG1-DG100 and DB1-DB100. It should be noted that since conducting wires 51 and 52 have line impedance, when the gamma voltage is transmitted by the conducting wires 51 and 52, it may be gradually attenuated, so that the DACs may receive different gamma voltages. As the impedance of the conducting wires 51 and 52 becomes greater, the gamma voltages received by the DACs are increasingly different.

Moreover, a charging time T of a capacitor C of the display panel 20 is 5*r*n*Cload, wherein 5 times r*Cload is a time constant for the capacitor C being charged to 99%, r is an average impedance between the buffer amplifiers and each channel, n is a number of channels driven by a single buffer amplifier. Since the impedance of the conducting wires 51 and 52 directly influences the r value, and the greater the impedance of the conducting wires 51 and 52 is, the longer the charging time T of the capacitor C is. If the charging time T is excessive long, it may influence the display quality of the display panel 20.

### SUMMARY OF THE INVENTION

The present invention is directed to a source driver, which may decrease an impedance of internal wiring.

The present invention is directed to an LCD, which may apply the aforementioned source driver to improve a display quality thereof.

The present invention provides a source driver including a plurality of pads, a first conducting wire, a second conducting wire, a plurality of first digital-to-analog converters (DACs), and a plurality of second DACs. The first conducting wire is coupled to a first voltage and the first DACs. The second conducting wire is coupled to a second voltage and the second DACs. The first DACs are disposed in a first layer, and output terminals of the first DACs are respectively coupled to a plurality of first pads included in the said pads. The second DACs are disposed in a second layer above the first layer, and output terminals of the second DACs are respectively coupled to a plurality of second pads included in the said pads.

In an embodiment of the present invention, the source driver further includes a buffer amplifier. An output terminal of the buffer amplifier is coupled to the first conducting wire and the second conducting wire for providing the first voltage and the second voltage. The buffer amplifier can be disposed in the first layer or the second layer.

In an embodiment of the present invention, the source driver further includes a first buffer amplifier and a second buffer amplifier. An output terminal of the first buffer amplifier is coupled to the first conducting wire for providing the first voltage. An output terminal of the second buffer amplifier is coupled to the second conducting wire for providing the second voltage.

In another embodiment of the present invention, the source driver further includes a third conducting wire, a fourth conducting wire, a third buffer amplifier and a fourth buffer amplifier. The third conducting wire is coupled to a third voltage and the first DACs. The fourth conducting wire is coupled to a fourth voltage and the second DACs. An output terminal of the third buffer amplifier is coupled to the third conducting wire for providing the third voltage. An output terminal of the fourth buffer amplifier is coupled to the fourth conducting wire for providing the fourth voltage.

In an embodiment of the present invention, the source driver further includes a third conducting wire and a plurality of third DACs. The third conducting wire is coupled to the third voltage and the third DACs. The third DACs are disposed in a third layer above the second layer, and output terminals thereof are correspondingly coupled to a plurality of third pads included in the said pads. In another embodiment, the first pads, the second pads and the third pads can be arranged in interleaving.

The present invention provides an LCD including a display panel and the aforementioned source driver. The display panel includes a pixel array coupled to a plurality of data lines. The data lines are correspondingly coupled to the pads of the source driver.

In the source driver of the present invention, the first conducting wire is coupled to the first voltage and a plurality of the first DACs, and the second conducting wire is coupled to the second voltage and a plurality of the second DACs. The first DACs are disposed in the first layer, and the second DACs are disposed in the second layer above the first layer. Therefore, signal transmission quality of the conducting wires can be improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a conventional LCD.

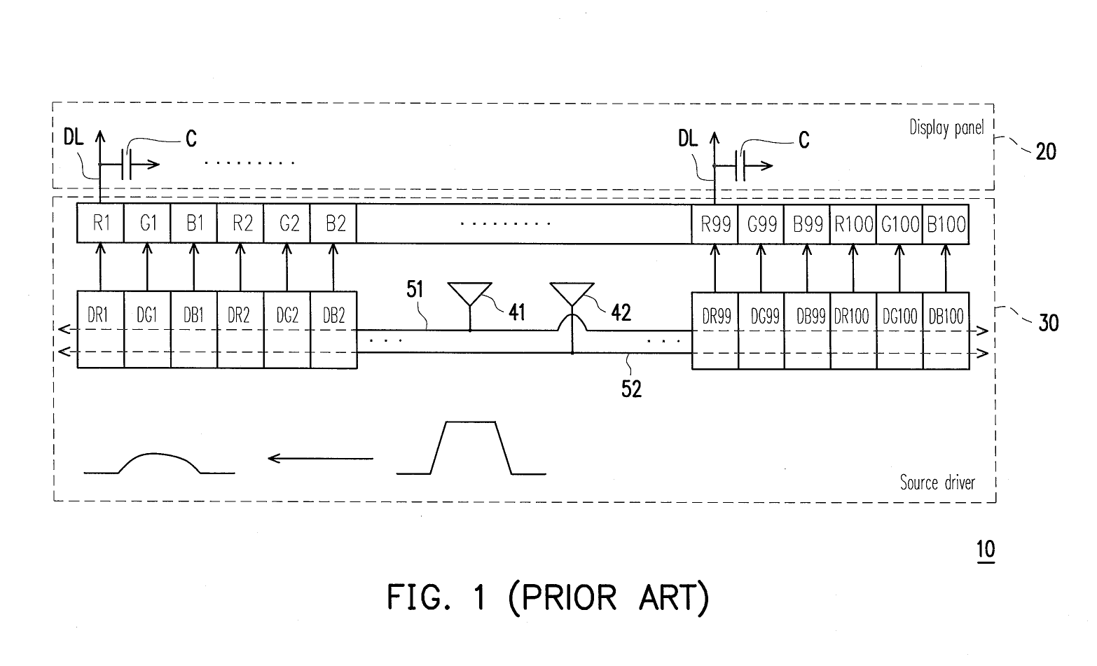

FIG. 2 is a schematic diagram illustrating an LCD according to a first embodiment of the present invention.

FIG. 3 is a schematic diagram illustrating an LCD according to a second embodiment of the present invention.

FIG. 4 is a schematic diagram illustrating an LCD according to a third embodiment of the present invention.

### DESCRIPTION OF EMBODIMENTS

In the conventional technique, the DACs of the source driver are all disposed in a same layer. Such method may lead to excessive impedance between the DACs and the buffer amplifiers within the source driver, so that display quality of the LCD is decreased. Accordingly, in embodiments of the present invention, a plurality of first DACs are disposed in a first layer, and a plurality of second DACs are disposed in a second layer, so as to resolve the problem of excessive impedance between the DACs and the buffer amplifiers within the source driver. Reference will now be made in detail to the present embodiments of the present invention, examples of which are illustrated in the accompanying drawings, wherein like reference numerals refer to the like elements or steps throughout.

### First Embodiment

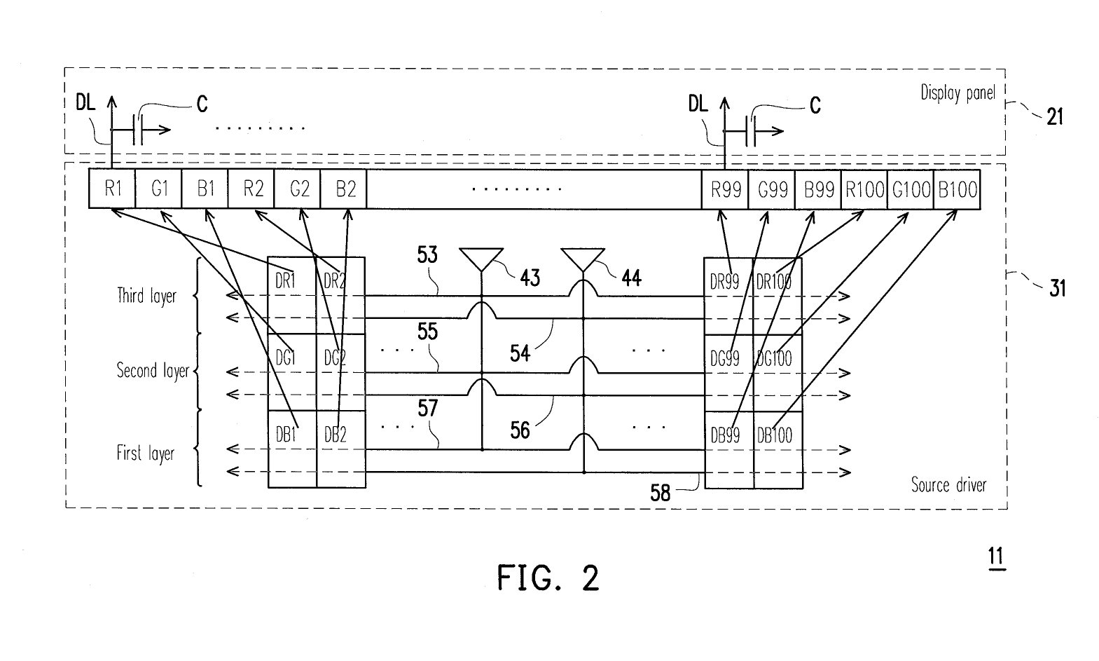

FIG. 2 is a schematic diagram illustrating an LCD according to a first embodiment of the present invention. Referring to FIG. 2, the LCD 11 includes a display panel 21 and a source driver 31. The display panel 21 may include a pixel array (not shown), a plurality of scan lines (not shown) and a plurality of data lines DL, wherein the pixel array is coupled to the scan lines and the data lines DL. The source driver 31 may include buffer amplifiers 43 and 44, conducting wires 53-58, DACs DR1-DR100, DG1-DG100 and DB1-DB100, and pads R1-R100, G1-G100 and B1-B100.

The buffer amplifier 43 is coupled to the conducting wires 53, 55 and 57. The buffer amplifier 44 is coupled to the conducting wires 54, 56 and 58. The conducting wires 53 and 54 are respectively coupled to the DACs DR1-DR100. The conducting wires 55 and 56 are respectively coupled to the DACs DG1-DG100. The conducting wires 57 and 58 are respectively coupled to the DACs DB1-DB100. The DACs DR1-DR100 are respectively coupled to the pads R1-R100. The DACs DG1-DG100 are respectively coupled to the pads G1-G100. The DACs DB1-DB100 are respectively coupled to the pads B1-B100. The pads R1-R100, G1-G100 and B1-B100 are correspondingly coupled to the data lines DL of the display panel 21. In FIG. 2, quantities of the buffer amplifiers, the conducting wires, the DACs and the pads and coupling method thereof are only an example, and the present invention is not limited thereto.

In the present embodiment, the buffer amplifier can be used for providing a gamma voltage. Particularly, the buffer amplifier 43 can provide a positive polarity gamma voltage to the conducting wires 53, 55 and 57. The buffer amplifier 44 can provide a negative polarity gamma voltage to the conducting wires 54, 56 and 58. The DACs DR1-DR100, DG1-DG100, and DB1-DB100 can convert digital signals into analog signals. To be specific, the DACs DR1-DR100 can convert the digital signals with red gray level into the analog signals, the DACs DG1-DG100 can convert the digital signals with green gray level into the analog signals, and the DACs DB1-DB100 can convert the digital signals with blue gray level into the analog signals. The pads R1-R100, G1-G100, and B1-B100 can function as signal output terminals of the source driver 31. To be more specific, the pads R1-R100 can function as output terminals of red analog signals, the pads G1-G100 can function as output terminals of green analog signals, and the pads B1-B100 can function as output terminals of blue analog signals. In the present embodiment, though the pads R1-R100, G1-G100 and B1-B100 are arranged in interleaving, the present invention is not limited thereto.

It should be noted that in the present embodiment, the DACs DB1-DB100 are disposed in a first layer, the DACs DG1-DG100 are disposed in a second layer, and the DACs DR1-DR100 are disposed in a third layer. Since the DACs are averagely disposed in the first to the third layers, an area of each layer can be effectively reduced. In the present embodiment, the buffer amplifiers 43 and 44 are disposed in the third layer, though the present invention is not limited thereto, and in other embodiments, the buffer amplifiers 43 and 44 can also be disposed at other positions such as the first layer or the second layer.

According to another aspect, in the present embodiment, since the DACs are averagely disposed in the first to the third layers, the area of each layer can be effectively reduced, and lengths of the conducting wires 53-58 are shortened accordingly. It is known by those skilled in the art that the impedance of the leading wire is proportion to the length thereof. Therefore, averagely disposing the DACs in the first to the third layers can effectively reduce the impedances of the conducting wires 53-58, so as to improve signal transmission qualities of the conducting wires 53-58. Besides, a charging time of a capacitor C of the display panel 21 can also be effectively shortened, so as to improve a displaying quality of the LCD 11.

In the present embodiment, only one source driver 31 is illustrated in FIG. 2, though the present invention is not limited thereto. It is known by those skilled in the art that different number of the source drivers can be disposed in the LCD 11 according to a size of the display panel 21, and implementing of the source drivers can be the same to that of the aforementioned source driver 31, and detailed description thereof will not be repeated.

Moreover, though the DACs are averagely disposed in the first layer, the second layer and the third layer, the present invention is not limited thereto. In other embodiments, the DACs of the source drivers 31 can also be dispatched in M layers, wherein M is a positive integer that is greater than or equal to 2. By such means, a similar function as the aforementioned embodiment can be achieved.

It should be noted that though in the aforementioned embodiment, a possible pattern of the LCD and the source driver has been described in the above embodiment, it should be understood by those skilled in the art that the design of the LCD and the source driver varies with manufacturers, thus, application of the present invention should not be limited to such possible pattern. In other words, the spirit of the present invention is still met as long as a plurality of the first DACs of the source driver is disposed in the first layer and a plurality of the second DACs of the source driver is disposed in the second layer. To fully convey the concept of the present invention to those skilled in the art, embodiments are provided below for describing the present invention in detail.

### Second Embodiment

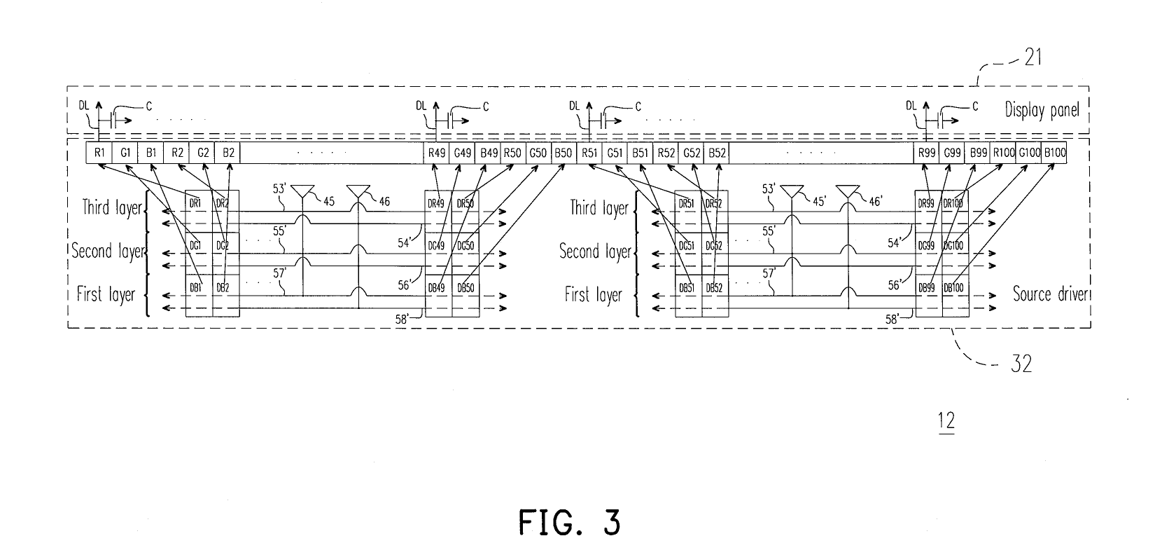

FIG. 3 is a schematic diagram illustrating an LCD according to a second embodiment of the present invention. Referring to FIG. 2 and FIG. 3, in the first embodiment, the buffer amplifiers 43 and 44 of the source driver 31 are respectively used for providing a gamma voltage to the three hundred DACs. Though, in other embodiments, different number of the buffer amplifiers can be disposed in the source driver to provide the gamma voltage to the DACs. For example, in a source driver 32 of the present embodiment, four buffer amplifiers 45, 46, 45′ and 46′ are applied. To be more specific, the buffer amplifiers 45 and 46 respectively provide the gamma voltage to the DACs DR1-DR50, DG1-DG50 and DB1-DB50, and the buffer amplifiers 45′ and 46′ respectively provide the gamma voltage to the DACs DR51-DR100, DG51-DG100 and DB51-DB100.

The buffer amplifiers 45, 46, 45′ and 46′ respectively provide the gamma voltage to the one hundred and fifty DACs, while the buffer amplifiers 43 and 44 respectively provide the gamma voltage to the three hundred DACs. Therefore, a length of the conducting wires 53′-58′ is only a half of the length of the conducting wires 53-58. As described in the first embodiment, the impedance of the conducting wire is proportion to the length thereof. Therefore, compared to the first embodiment, the signal transmission quality of the conducting wires 53-58 can be further improved, the charging time of the capacitor C of the display panel 21 can be shortened, and the display quality of the LCD 12 can be improved. In the following content, another embodiment is provided for further description.

### Third Embodiment

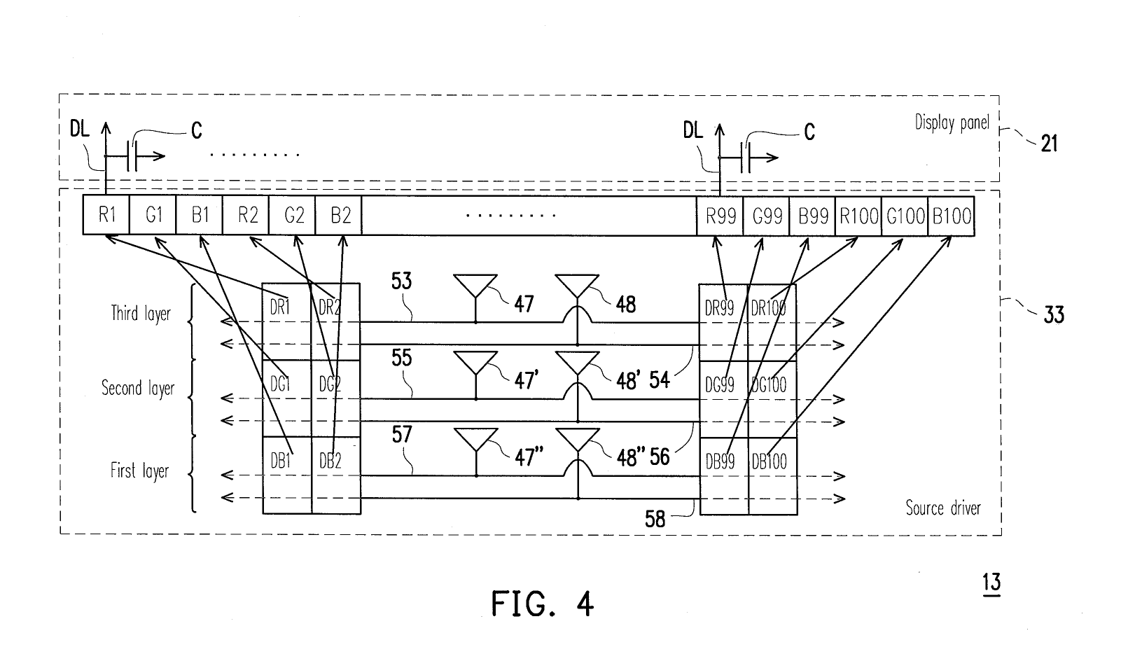

FIG. 4 is a schematic diagram illustrating an LCD according to a third embodiment of the present invention. Referring to FIG. 2 and FIG. 4, a source driver 33 of the LCD 13 applies six buffer amplifiers 47, 48, 47′, 48′, 47″ and 48″. The buffer amplifiers 47″ and 48″ are disposed in the first layer for respectively providing the gamma voltage to the DACs DB1-DB100. The buffer amplifiers 47′ and 48′ are disposed in the second layer for respectively providing the gamma voltage to the DACs DG1-DG100. The buffer amplifiers 47 and 48 are disposed in the third layer for respectively providing the gamma voltage to the DACs DR1-DR100. In the present embodiment, the buffer amplifiers 47, 48, 47′, 48′, 47″ and 48″ of the source driver 33 respectively provide the gamma voltage to the one hundred DACs, and the buffer amplifier 43 and 44 of the source driver 31 of the first embodiment respectively provide the gamma voltage to the three hundred DACs. Compared to FIG. 2, the source driver 33 of FIG. 4 not only has similar functions as the source driver 31 of FIG. 2, but may also improve a driving capability of the buffer amplifiers thereof.

In summary, in the source driver of the present invention, a plurality of the DACs is dispatched in multi layer. Therefore, the area of each layer can be reduced. Moreover, the embodiments of the present invention have at least the following advantages:
1. Since the area of each layer is reduced, the lengths of the conducting wires between the buffer amplifiers and the DACs are shortened accordingly, and since the length of the conducting wire is proportion to the impedance, as the lengths of the conducting wires are shortened, the signal transmission quality of the conducting wires can be improved.
2. Since the charging time of the capacitor of the display panel is proportion to the impedance of the conducting wire (the impedance of the conducting wire between the buffer amplifier and the DAC), as the length of the conducting wire is shortened, the charging time of the capacitor of the display panel is shortened accordingly, so that the display quality of the LCD is improved.

3. The DACs are divided into a plurality of regions, and suitable number of buffer amplifiers is disposed in each region for providing the gamma voltage to the DACs of each region. By such means, the length of the conducting wire between the buffer amplifier and the DAC can be further reduced.
4. Increasing the number of the buffer amplifiers of the source driver can enhance the driving capability of the buffer amplifiers.

It will be apparent to those skilled in the art that various modifications and variations can be made to the structure or the present invention without departing from the scope or spirit of the invention. In view of the foregoing, it is intended that the present invention cover modifications and variations of this invention provided they fall within the scope of the following claims and their equivalents.

What is claimed is:

1. A source driver, comprising:
a plurality of pads;
a first conducting wire, coupled to a first voltage;
a second conducting wire, coupled to a second voltage;
a plurality of first digital-to-analog converters (DACs), disposed in a first layer, and coupled to the first conducting wire, wherein output terminals of the first DACs are correspondingly coupled to a plurality of first pads included in the pads; and
a plurality of second DACs, disposed in a second layer above the first layer, and coupled to the second conducting wire, wherein output terminals of the second DACs are correspondingly coupled to a plurality of second pads included in the pads.

2. The source driver as claimed in claim 1, further comprising:
a buffer amplifier, having an output terminal coupled to the first conducting wire and the second conducting wire for providing the first voltage and the second voltage.

3. The source driver as claimed in claim 2, wherein the buffer amplifier is disposed in the first layer or the second layer.

4. The source driver as claimed in claim 1, further comprising:
a first buffer amplifier, having an output terminal coupled to the first conducting wire for providing the first voltage; and
a second buffer amplifier, having an output terminal coupled to the second conducting wire for providing the second voltage.

5. The source driver as claimed in claim 4, further comprising:
a third conducting wire, coupled to a third voltage and the first DACs;
a fourth conducting wire, coupled to a fourth voltage and the second DACs;
a third buffer amplifier, having an output terminal coupled to the third conducting wire for providing the third voltage; and
a fourth buffer amplifier, having an output terminal coupled to the fourth conducting wire for providing the fourth voltage.

6. The source driver as claimed in claim 1, further comprising:
a third conducting wire, coupled to a third voltage; and
a plurality of third DACs, disposed in a third layer above the second layer, and coupled to the third conducting wire, wherein output terminals of the third DACs are correspondingly coupled to a plurality of third pads included in the pads.

7. The source driver as claimed in claim 6, wherein the first pads, the second pads and the third pads are arranged in interleaving.

8. An LCD, comprising:
a display panel, comprising a pixel array coupled to a plurality of data lines; and
a source driver, comprising:
a plurality of pads, correspondingly coupled to the data lines;
a first conducting wire, coupled to a first voltage;
a second conducting wire, coupled to a second voltage;
a plurality of first DACs, disposed in a first layer, and coupled to the first conducting wire, wherein output terminals of the first DACs are correspondingly coupled to a plurality of-first pads included in the pads; and
a plurality of second DACs, disposed in a second layer above the first layer, and coupled to the second conducting wire, wherein output terminals of the second DACs are correspondingly coupled to a plurality of second pads included in the pads.

9. The LCD as claimed in claim 8, wherein the source driver further comprises:
a buffer amplifier, having an output terminal coupled to the first conducting wire and the second conducting wire for providing the first voltage and the second voltage.

10. The LCD as claimed in claim 9, wherein the buffer amplifier is disposed in the first layer or the second layer.

11. The LCD as claimed in claim 8, wherein the source driver further comprises:
a first buffer amplifier, having an output terminal coupled to the first conducting wire for providing the first voltage; and
a second buffer amplifier, having an output terminal coupled to the second conducting wire for providing the second voltage.

12. The LCD as claimed in claim 11, wherein the source driver further comprises:
a third conducting wire, coupled to a third voltage and the first DACs;
a fourth conducting wire, coupled to a fourth voltage and the second DACs;
a third buffer amplifier, having an output terminal coupled to the third conducting wire for providing the third voltage; and
a fourth buffer amplifier, having an output terminal coupled to the fourth conducting wire for providing the fourth voltage.

13. The LCD as claimed in claim 8, wherein the source driver further comprises:
a third conducting wire, coupled to a third voltage; and
a plurality of third DACs, disposed in a third layer above the second layer, and coupled to the third conducting wire, wherein output terminals of the third DACs are correspondingly coupled to a plurality of third pads included in the pads.

14. The LCD as claimed in claim 13, wherein the first pads, the second pads and the third pads are arranged in interleaving.
